(19) United States
(12) Patent Application Publication
(10) Pub. No.: US 2017/0154853 A1
(43) Pub. Date: Jun. 1, 2017

(54) METHOD FOR SINGULATING A MULTIPLICITY OF CHIPS

(71) Applicant: Infineon Technologies AG, Neubiberg (DE)

(72) Inventors: Frank Pueschner, Kelheim (DE); Peter Stampka, Burglengenfeld (DE)

(21) Appl. No.: 15/364,306

(22) Filed: Nov. 30, 2016

(30) Foreign Application Priority Data
Nov. 30, 2015 (DE) 10 2015120 755.9

(51) Int. Cl. H01L 23/544; H01L 21/304; H01L 21/3065; H01L 21/78

(52) U.S. Cl. CPC H01L 23/544; H01L 21/78; H01L 21/304; H01L 21/3065; H01L 2223/5446

(57) ABSTRACT

A method for singulating a multiplicity of chips is provided. Each chip includes a substrate, an active region arranged at least one of in or on the substrate, at least one electronic component being formed in said active region, and a dielectric above the active region. The method includes forming at least one first trench between the chips. The at least one first trench is formed through the dielectric and the active regions and extends into the substrate. The method further includes sawing the substrate material from the opposite side of the substrate relative to the first trench along a sawing path corresponding to the course of at least one first trench, such that at least one second trench is formed. The width of the at least one first trench is less than or equal to the width of the at least one second trench.

### CROSS-REFERENCE TO RELATED APPLICATION

This application claims priority to German Patent Application Serial No. 10 2015 120 755.9, which was filed Nov. 30, 2015, and is incorporated herein by reference in its entirety.

### TECHNICAL FIELD

The present disclosure relates to methods for singulating a multiplicity of chips.

### BACKGROUND

Starting material, such as a semiconductor wafer, for example, represents a significant cost factor in chip production. Accordingly, a method which increases the number of chips which can be formed per semiconductor wafer and reduces the material loss during singulation of a multiplicity of chips is of major importance.

One conventional method for singulating a multiplicity of chips, such as, for example, sawing a wafer by means of a saw blade, is widely used on account of the method speed achievable. However, the sawing can mechanically load and damage a chip. The chip or a part of the chip can splinter and be damaged on account of the formation of cracks. A laser is used in another conventional method. Such a method can likewise lead to damage in a chip on account of energy input, associated with a corresponding temperature. Furthermore, in a further conventional singulating method, plasma etching is used for singulation. In this case, too, for example if the plasma etching is applied to a chip for an excessively long time duration, the chip can be damaged.

### SUMMARY

A method for singulating a multiplicity of chips is provided. Each chip includes a substrate, an active region arranged at least one of in or on the substrate, at least one electronic component being formed in said active region, and a dielectric above the active region. The method includes forming at least one first trench between the chips. The at least one first trench is formed through the dielectric and the active regions and extends into the substrate. The method further includes sawing the substrate material from the opposite side of the substrate relative to the first trench along a sawing path corresponding to the course of at least one first trench, such that at least one second trench is formed. The width of the at least one first trench is less than or equal to the width of the at least one second trench.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A shows a cross-sectional view of a multiplicity of chips at a first point in time of a method for singulating the multiplicity of chips in accordance with various embodiments;;

FIG. 1B shows a cross-sectional view of a multiplicity of chips at a second point in time of a method for singulating the multiplicity of chips in accordance with various embodiments;

FIG. 1C shows a cross-sectional view of a multiplicity of chips at a third point in time of a method for singulating the multiplicity of chips in accordance with various embodiments;

FIG. 1D shows a cross-sectional view of a multiplicity of chips at a fourth point in time of a method for singulating the multiplicity of chips in accordance with various embodiments;

FIG. 2A shows a cross-sectional view of a multiplicity of chips at a first point in time of a method for singulating the multiplicity of chips in accordance with various embodiments;

FIG. 2B shows a cross-sectional view of a multiplicity of chips at a second point in time of a method for singulating the multiplicity of chips in accordance with various embodiments;

FIG. 2C shows a cross-sectional view of a multiplicity of chips at a third point in time of a method for singulating the multiplicity of chips in accordance with various embodiments;

FIG. 2D shows a cross-sectional view of a multiplicity of chips at a fourth point in time of a method for singulating the multiplicity of chips in accordance with various embodiments; and

FIG. 3 shows a method for singulating chips.

### DESCRIPTION

In the following detailed description, reference is made to the accompanying drawings, which form part of this description and show for illustration purposes specific embodiments in which the invention can be implemented. In this regard, direction terminology such as, for instance, “at the top”, “at the bottom”, “at the front”, “at the back”, “front”, “rear”, etc. is used with respect to the orientation of the figure(s) described. Since components of embodiments can be positioned in a number of different orientations, the direction terminology serves for illustration and is not restrictive in any way whatsoever. It goes without saying that other embodiments can be used and structural or logical changes can be made, without departing from the scope of protection of the present invention. It goes without saying that the features of the various embodiments described herein can be combined with one another, unless specifically indicated otherwise. Therefore, the following detailed description should not be interpreted in a restrictive sense, and the scope of protection of the present invention is defined by means of the appended claims.

In the context of this description, the terms “connected” and “coupled” are used to describe both a direct and an indirect connection and a direct or indirect coupling. In the figures, identical or similar elements are provided with identical reference signs, insofar as this is expedient.

Illustratively, in various embodiments for singulating the chips of a wafer, provision can be made firstly for applying an etching process on the front side, for example, in such a way that trenches are formed, for example etched, with a depth such that the trenches extend completely through the “front-side” dielectric and completely through the region of the wafer in which the electronic components are formed in the respective chips (also designated as the active region). Afterward, a sawing process is applied to the rear side of the wafer such that “rear-side” trenches are formed which substantially correspond to the “front-side” trenches in their course. The “rear-side” trenches are formed with a depth such that illustratively they “open” the bottom of the “front-side” trenches, whereby the singulation of the chips is achieved. The process for forming the trenches that is applied to the front side has a higher accuracy than the sawing process applied to the rear side of the wafer. As a result, it becomes possible to configure the “front-side” trenches very narrowly and to carry out the “rear-side” sawing very rapidly. Moreover, the front-side processing (which is carried out in direct proximity to the chips) exhibits considerably less mechanical loading than the sawing process with regard to the chips to be singulated. Moreover, the high accuracy of the front-side trench forming process makes it possible to reduce the size of the singulation regions (often also referred to as sawing street), as a result of which more chips can be formed on the wafer. The mechanically “loading” sawing process is substantially carried out in a region that is far enough away from the chips, such that damage to the chips as a result of the sawing process is kept small.

A chip may include a substrate, an active region arranged in and/or on the substrate, at least one electronic component being formed in said active region, and a dielectric above the active region. A method for singulating a multiplicity of chips may include forming at least one first trench between the multiplicity of chips. The at least one first trench is formed through the dielectric and the active regions and extends into the substrate. The method may furthermore include sawing the substrate material, from the opposite side of the substrate relative to the first trench. The sawing can be carried out along a sawing path corresponding to the course of the at least one first trench, such that at least one second trench is formed. The width of the at least one first trench can be less than or equal to the width of the at least one second trench.

The multiplicity of chips can be formed in and/or on a common substrate. Accordingly, the multiplicity of chips before singulation is referred to hereinafter as wafer. The wafer has a first wafer surface, at which the multiplicity of chips are formed. The second, opposite wafer surface is also called the substrate side of the wafer. Before the singulation of the multiplicity of chips, the wafer may include a (continuous) substrate, wherein for example a dielectric is formed over an entire area of the substrate of the wafer. Accordingly, the wafer can be considered for example such that, before the singulation of the multiplicity of chips, each chip of the multiplicity of chips includes for example a partial region of the substrate of the wafer and a partial region of the dielectric of the wafer.

Active region denotes the region of a chip in which one or a plurality of active and/or passive electrical components are formed. The active region is not necessarily limited to said one or said plurality of electrical components.

The active region can extend into the substrate and/or be formed on a side of the substrate. The one or the plurality of electrical components can be for example an element of an integrated circuit, such as, for example, a diode, a transistor and/or, for example, a component of CMOS technology.

Before the singulation of the multiplicity of chips, the wafer may include a (continuous) active region which can have a multiplicity of active (partial) regions of the multiplicity of chips. Accordingly, forming at least one first trench through the multiplicity of active regions of the multiplicity of chips can be understood such that the active region of a respective chip is delimited in its geometrical shape on account of the singulation of the multiplicity of chips. One or a plurality of protective and/or encapsulation layers can be formed on the multiplicity of active (partial) regions of the multiplicity of chips and on the dielectric.

The multiplicity of chips can be formed in and/or on a substrate, for example a semiconductor material. The substrate may include for example silicon, germanium, gallium arsenide and/or some other semiconductor material, which can be doped. The chips can be formed using various production processes, for example processes of doping, of photolithography, of deposition, of metallization and/or of etching. During the method, the wafer can be mounted by means of one or more corresponding devices, for example by the wafer being held by means of clamping and/or by means of a reduced pressure. Between the multiplicity of chips, regions of the wafer are provided for the singulation of the chips.

The wafer may additionally include a multiplicity of process control elements. A process control element can be for example an alignment marking, a structure for monitoring the layer thickness and/or an electrical control structure. An electrical control structure can be a circuit such as, for example, a PCM (Process Control Monitor) or, for example, an RCM (Reliability Control Monitor). Such a circuit, which may include copper and/or aluminum, for example, can be formed between the chips in and/or on the substrate, for example on the dielectric. A process control element, like a respective chip, too, may include an active (partial) region. On account of the singulation of the multiplicity of chips, a process control element can be at least partly removed. A process control element, for example an alignment marking, can facilitate and/or enable the positioning of the at least one first trench. A process control element may include one or a plurality of electrical connections to a chip of the multiplicity of chips. Such an electrical connection can be interrupted by means of the formation of the at least one first trench.

The at least one first trench can extend from the first wafer surface with a maximum trench depth into the substrate. The maximum trench depth is the distance between the first wafer surface and the deepest point of the trench (as viewed from the first wafer surface). The maximum trench depth can be locally different, for example on account of the production method. The at least one first trench has a first trench width at the first wafer surface. Depending on the production method, the first trench width at the first wafer surface can differ from the trench width at the level of the maximum trench depth, i.e. can have a variable trench width. By way of example, the at least one first trench can taper, the further it reaches into the substrate. Analogously, the at least one second trench has a first trench width and a maximum trench depth and can have a variable trench width.

The at least one first trench and the at least one second trench can be designed in such a way that the wafer is opened on account of the formation of the at least one first trench and the at least one second trench and the multiplicity of chips are detached from one another and thus singulated. The maximum trench depth of the at least one first trench and the maximum trench depth of the at least one second trench can in total be greater than the thickness of the wafer.

The at least one first trench and the at least one second trench can have one or more local differences in the maximum trench depth. Forming the at least one first trench and forming the at least one second trench may not open the wafer or may only open it locally. In the case where the wafer is not opened or is only opened locally by means of the at least one first trench and the at least one second trench, the method for singulating the chips may furthermore include for example mechanically breaking the wafer along the at least one first trench. By way of example, the method can be part of a so-called “pick, crack and place” method. That is to say that a chip can be broken away from a wafer for example by means of a vacuum device.

Forming the at least one first trench and the at least one second trench can be carried out by means of various methods. By way of example, a method for forming a respective first trench can be designed to be gentle, that is to say that the multiplicity of chips are subjected to as little mechanical loading as possible and/or to the lowest possible energy input, depending on the method. By way of example, the method can be specifically adapted to a mechanical loading capacity, such as, for example, the mechanical loading capacity of a dielectric. However, such a method can be complex and/or time-intensive. Further methods that can be used, in principle, in chip singulation can have a high method speed or a high ease of maintenance, although such a method may often expose the chips to considerable mechanical loads. One example of such a process is a sawing process. The combination of a method which has a high accuracy and exerts only a relatively low mechanical loading on the chips, for forming the at least one first trench, with a very fast and cost-effective method (a sawing process) for forming the at least one second trench makes it possible to utilize the respective advantages in the respective processing areas whilst largely avoiding their respective disadvantages. In other words, the method for forming the at least one first trench and the method for forming the at least one second trench can be combined with one another such that the chips are treated gently and a high (total) method speed is nevertheless achieved in the singulation of the chips.

The first trench width of the first trench at the first wafer surface can be less than or equal to the first trench width of the second trench at the second wafer surface. Furthermore, any trench width of the first trench, for example in the case where the trench width of the first trench is variable, can be less than or equal to any trench width, for example in the case where the trench width of the second trench is variable, of the second trench. Any trench width should be understood to mean the trench width at different levels between the trench width at the level of the first wafer surface (the first trench width) and the trench width at the level of the maximum trench depth.

The method for forming the at least one first trench can be optimized for example to the effect of achieving the smallest possible feature size, for example a first trench width of less than 20 μm, for example 10 μm or less, for example less than 4 μm. This makes it possible to position the chips in the wafer even closer to one another, as a result of which the achievable chip density per wafer can be increased, without reducing the yield of defect-free chips.

In accordance with various exemplary embodiments, before sawing the substrate material, the substrate can be thinned to a desired substrate thickness.

Thinning the substrate can be performed by means of various methods, such as, for example, grinding, polishing and/or etching. By way of example, before singulation, the substrate can have a thickness which is necessary or advantageous for forming a multiplicity of chips. The thinning can serve to produce a desired thickness of the multiplicity of chips. Furthermore, the thinning can serve for example to ensure that the mechanical loading of the substrate and of the multiplicity of chips is reduced by virtue of the fact that, after thinning, a smaller maximum trench depth of the at least one second trench may be necessary in order, illustratively, to reach the bottom of a respective first trench on the rear side and thus, illustratively, to open the respective first trench on the bottom side. The thinning can be carried out in order to optimize the thermal conductivity of a chip.

In accordance with various embodiments, the at least one first trench can be formed by means of etching.

An etching method can be characterized for example inter alia by the fact that a smaller minimum achievable trench depth can be produced in comparison with other methods. An etching method is usually gentler, for example exhibits less mechanical loading, than a sawing process. An etching method can be adapted to the material to be etched. To protect a surface region which is not intended to be processed, it is possible to use a mask and/or one or more protective layers, which optionally can be removed again after the etching.

In accordance with various embodiments, the at least one first trench can be formed by means of plasma etching.

In a plasma method such as plasma etching, one or a plurality of wafers can be processed in one work operation, for example. In plasma etching, the temperature of the wafer can be monitored and controlled by means of a suitable device, for example by means of a cooled chuck. Plasma etching may include one or a plurality of further plasma treatments. One or a plurality of plasma treatments can include one or a plurality of cleaning processes. In this regard, before the plasma etching, for example, an ammonia- or oxygen-based plasma can be used to remove an organic contaminant or some other residue. Plasma etching can be advantageous since a very accurately defined and small first trench width can be made possible. By way of example, a trench width of the at least one first trench of less than 5 μm can be achieved.

In accordance with various embodiments, the composition of the plasma and/or the excitation of the plasma can be altered during the plasma etching.

A method based on the use of plasma can have the effect that a plurality of parameters are variable during the method. By way of example, the type of gas or gas mixture, for example the concentration of a component, can be altered. This can greatly influence the processing of a material. By way of example, the etching rate can be influenced depending on the gas/gas mixture and the material to be processed. The working gas of the plasma can have a wide variety of effects. In this regard, a noble gas, such as argon, for example, can be used to minimize a chemical reaction. In contrast thereto, oxygen, for example, can be used to form an oxide. The temperature of the wafer can be regulated during the plasma etching by means of a suitable holder, for example, in order to influence the etching rate. Depending on the production of the plasma and the specification of a corresponding plasma reactor, the kinetic energy of the ions in the plasma can be influenced, for example. In this regard, one or a plurality of constant and/or varying electric and/or magnetic fields can be designed to vary the kinetic energy of the ions. Accordingly, the plasma etching during the process of forming the at least one first trench can be adapted to the material that is currently to be etched. Consequently, the plasma etching can be optimized, for example, firstly to be gentle for the material to be etched and secondly to have a high (total) etching rate, for example for the case where the respective first trench extends through a plurality of different materials arranged one above another. Gently treating the material to be etched can mean, for example, that the energy input into the material is comparatively low and/or that the plasma etching is comparatively less time-intensive.

In accordance with various embodiments, the sawing can be carried out by means of a saw blade.

The sawing by means of a saw blade can have a high method speed and be comparatively cost-effective in comparison with other methods. The sawing by means of a saw blade can be supported by means of an adhesive sawing film being applied to the wafer. Less complexity in a method can mean, for example, that no time-intensive preparation is necessary, such as, for example, applying a protective layer or producing a vacuum.

In accordance with various embodiments, the at least one first trench can be formed with a maximum trench depth in a range of approximately 5 μm to approximately 50 μm.

A maximum trench depth of the at least one first trench can be in the range of approximately 5 μm to approximately 50 μm, for example of approximately 5 μm to approximately 25 μm, for example of approximately 5 μm to approximately 10 μm. The maximum trench depth of the at least one first trench can be optimized to ensure that the overall method is gentle and the overall method speed is optimized. Optimizing can mean, for example, that the multiplicity of chips are damaged and/or influenced as little as possible, that the overall method speed is high, and/or that the method is cycled as accurately as possible in a production chain.

A method for forming a trench can for example include the fact that the trench width tapers, i.e. the first trench width at the wafer surface is greater than the trench width at the level of the maximum trench depth. In other words, the maximum trench depth is limited on account of a desired first trench width at the wafer surface and can accordingly be the subject of an optimization.

In accordance with various embodiments, the multiplicity of chips can be formed at a distance of approximately 3 μm to approximately 10 μm from one another.

The distance between the multiplicity of chips, which distance can vary, influences the number of the multiplicity of chips which can be formed per wafer. Since the at least one first trench is formed between the chips, accordingly the maximum first trench width of the first trench at the first wafer surface and, depending on the production method, thus also the maximum trench depth of the first trench can be dependent on said distance. In this context it should be pointed out that the trench width of the second trenches can be so large that the second trenches laterally overlap the chips. This does not pose a problem, however, since, after all, the first trenches extend completely through the dielectric and the active region and are thus formed deeper than the chips, and thus for singulating the chips the second trenches are formed with a stop below the chips.

In accordance with various embodiments, the dielectric can have a dielectric constant of less than or equal to 3.9.

In the production of a multiplicity of chips or one or more other elements, such as, for example, a multiplicity of process control elements, a dielectric, such as SiCOH, for example, can be used which can have a lower dielectric constant than silicon oxide. Such a material is also referred to as “low-k” and “ultra-low-k” material. The dielectric is used, for example, in order to influence the so-called “RC delay” (i.e. capacitive and/or resistive effects). In order to reduce the dielectric constant, the dielectric can be present in the form of a porous layer. Such a porous layer can be mechanically influenced or damaged comparatively more easily. Moreover, the dielectric can have a comparatively low adhesion. Precisely in the case of such a dielectric, avoiding a sawing process for severing the dielectric in accordance with various embodiments is gentle for the chips and the use of an etching process (also adaptable toward the concrete dielectric(s)) can considerably reduce the occurrence of damage in the dielectric and thus in the chips.

In accordance with various embodiments, the width of at least one second trench can be greater than the distance between two adjacent first trenches, such that the two adjacent first trenches are opened on the rear side during the process of sawing the at least one second trench.

By way of example, two or more first trenches can be opened on account of the formation of the at least one second trench. As a result, for example, the number of second trenches required can be reduced, which reduces the mechanical loading of the multiplicity of chips and can shorten the duration of the entire singulating process.

In accordance with various embodiments, the at least one first trench can extend into the substrate more deeply than the multiplicity of active regions of the multiplicity of chips.

By virtue of the fact that the at least one first trench extends into the substrate for example more deeply than the multiplicity of the active regions of the multiplicity of chips, for example the maximum trench depth of the at least one second trench, in order to open the wafer, can be reduced. By way of example, mechanical loading on the multiplicity of the active regions of the multiplicity of chips on account of the formation of the second trench can thus be reduced.

In accordance with various embodiments, a wafer may include a multiplicity of chips. The substrate can have a thickness of a maximum of approximately 250 μm. The wafer can be provided with a protective layer on the first wafer surface. Said protective layer, which for example consists of carbon or includes carbon, can have a plurality of openings. Said plurality of openings can be arranged between the multiplicity of chips. The protective layer having the plurality of openings can thus serve as a mask. By way of example, the wafer includes hundreds of chips and the plurality of openings form a lattice-shaped basic area. The wafer with the protective layer is subsequently mounted in a holder and introduced into a plasma reactor. By means of plasma etching, a plurality of first trenches, for example hundreds of first trenches, can be formed on the first wafer surface in the plurality of openings of the protective layer in one operation. The plurality of first trenches can have a first trench width of 4 μm and a maximum trench depth of 30 μm. The plurality of first trenches can have a variable trench width such that the plurality of first trenches taper, with the result that the trench width at the level of the maximum trench depth is 1 μm. Afterward, the wafer is removed from the plasma reactor and the protective layer can optionally be removed. Alternatively, the protective layer can also be removed by means of another plasma process. The wafer is subsequently provided with an adhesive sawing film and introduced into a sawing device (for example by means of a suitable holder). The plurality of second trenches produced by means of sawing by means of a saw blade can have a maximum trench depth of approximately 225 μm. The plurality of second trenches produced by means of sawing by means of a saw blade can have a maximum trench depth that is small enough that the second trenches still do not extend into the active regions of the chips.

The first trench width of the plurality of second trenches at the second wafer surface can be 50 μm, for example, on account of the thickness of the saw blade. The plurality of first trenches and the plurality of second trenches are positioned such that the wafer is opened at the plurality of positions of the plurality of first trenches. The adhesive sawing film prevents the thus singulated multiplicity of chips from detaching from one another during sawing. Afterward, the multiplicity of chips are removed from the adhesive sawing film for example mechanically and/or by means of a vacuum device.

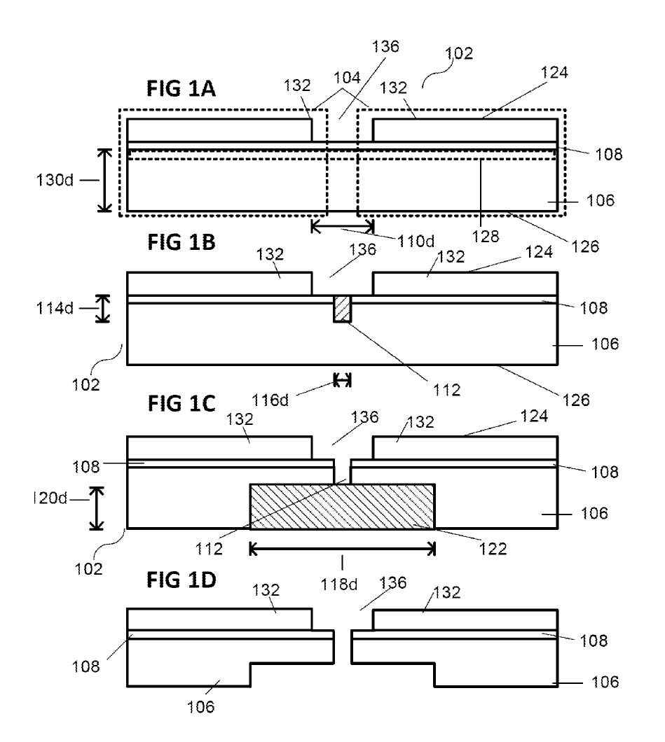

FIG. 1A shows a cross-sectional view of a multiplicity of chips 104 at a first point in time of a method for singulating the multiplicity of chips 104 in accordance with various embodiments.

The multiplicity of chips before singulation are referred to hereinafter as wafer.

In this embodiment, a wafer 102 before singulation includes a multiplicity of chips, wherein two chips 104 of the multiplicity of chips are illustrated in FIG. 1A.

The wafer 102 has a first wafer surface 124 and a second wafer surface 126, said second wafer surface being opposite the first wafer surface 124. The wafer 102 includes a substrate 106 having a substrate thickness 130d. A dielectric 108 is formed above the substrate 106. The wafer 102 includes an active region 128, in which one or a plurality of electronic components (not shown) such as, for example, one or a plurality of transistors are formed. The active region 128 extends in the substrate 106 and is covered by the dielectric 108. Two layer structures 132 are formed on the dielectric 108, wherein each layer structure 132 covers a part of the active region 128, wherein each layer structure 132 laterally delimits a respective chip 104, for example. The two chips 104 are at a distance 110d from one another.

In this embodiment, the substrate 106 is a doped silicon substrate. Alternatively, the substrate 106 may include an arbitrary other semiconductor material, for example germanium or gallium arsenide, or some other compound semiconductor material, which can be doped. The compound semiconductor material can be a binary compound semiconductor material or a ternary compound semiconductor material or else a quaternary compound semiconductor material.

Generally, the substrate 106 can have for example a thickness 130d in a range of approximately 50 μm to approximately 1 mm, for example in a range of approximately 100 μm to 500 μm. In one concrete example, the substrate 106 has a thickness 130d of approximately 200 μm.

In various embodiments, the dielectric 108 may include one or a plurality of dielectric layers. The dielectric 108 or one or a plurality of dielectric layers which the dielectric 108 includes may include for example SiCOH, SiN, SiC, SiO and/or AlO (in each case in different stoichiometric ratios) and be applied for example by means of a CVD method (Chemical Vapor Deposition), for example PECVD (Plasma Enhanced Chemical Vapor Deposition), or by means of an ALD method (Atomic Layer Deposition). In one concrete embodiment, the dielectric 108 is a porous SiCOH layer.

In various embodiments, a plurality of metallizations can be formed in the dielectric 108. By way of example, one or a plurality of metallizations, for example structured metal layers (also referred to as metallization planes) and/or contact vias, can be formed in the dielectric 108. One or a plurality of metallizations can be electrically connected to electrical components of the multiplicity of chips.

The active region 128 is defined here as the region of the wafer 102 in which one or a plurality of electrical components of the multiplicity of chips can be formed. Electrical components can be for example transistors, diodes and/or electrical connections. An electrical component can be formed for example in accordance with CMOS technology inter alia by means of one or a plurality of photolithography, doping, deposition and/or metallization processes.

In various embodiments, the layer structure 132 may include one or a plurality of metallization and dielectric structures. By way of example, a layer structure 132 can serve as protection of the electrical components of the chips 104. Depending on the embodiment, a layer structure 132 may not be present or may be constructed differently. In one concrete example the layer structure 132 includes silicon nitride.

FIG. 1B shows a cross-sectional view of a multiplicity of chips 104 at a second point in time of a method for singulating the multiplicity of chips 104 in accordance with various embodiments.

Proceeding from said wafer 102, afterward, as illustrated in FIG. 1B, a first trench 112 is formed in the gap 136 between the two chips 104. To put it another way, the first trench is formed in each case in a region that is free of any electrical component of the chip (even if, for example, test components such as, for example, test circuit structures, such as PCM structures, can be present in the region, which are then destroyed during the singulation of the chips 104).

The first trench 112 has a maximum trench depth 114d and a first trench width 116d.

In accordance with various embodiments, the first trench 112 can be formed by means of a photolithography process and a plasma etching process. The photolithography process and the plasma etching are explained in greater detail below.

In various embodiments, for a photolithography process, a photoresist layer (not illustrated) is applied to the first wafer surface 124 of the wafer 102, for example by means of spin coating.

The photoresist layer is partly exposed for example by means of a lithography mask and UV light and for example the exposed parts of the photoresist layer are subsequently removed by means of a chemical treatment. A region of the first wafer surface 124 through which the first trench 112 is formed is uncovered as a result. The residual photoresist layer still remaining on the first wafer surface 124 is used as a protective layer vis-à-vis the plasma etching which then follows.

For the plasma etching, the wafer 102 can be introduced into a plasma reactor. The plasma, which may include argon as working gas, for example, etches through the dielectric 108 and into the substrate 106 (and thus into the active region 128). In various embodiments, the excitation of the plasma and/or the composition of the plasma can be altered during the plasma etching in order, for example, to adapt the etching behavior and the etching rate to the material of the wafer 102 that is currently to be etched, for example silicon.

During the plasma etching, the plasma reaches the wafer 102 only in that region of the first wafer surface 124 which is freed of the photoresist layer and through which the first trench 112 is formed. The plasma etching is carried out until a desired predefined maximum trench depth 114d is reached.

After the plasma etching, the residual photoresist layer is removed by means of a further chemical treatment. The wafer 102 then has the form illustrated schematically in FIG. 1B.

The first trench width 116d, for example limited on account of the distance 110d, can be for example 3 μm to 100 μm, for example 5 μm to 30 μm. In one concrete example, the first trench width 116d is approximately 5 μm.

The maximum trench depth 114d can be for example 1 μm to 50 μm, for example 3 μm to 25 μm. In one concrete example, the maximum trench depth 114d extends approximately 15 μm into the substrate 106.

In one example, the first trench 112 extends into the substrate 106 more deeply than the active region 128 of the wafer 102, such that during a subsequent process of rear-side sawing for forming a second trench 122 (see FIG. 1C), the active region 128 is not damaged on account of the sawing.

FIG. 1C shows a cross-sectional view of a multiplicity of chips 104 at a third point in time of a method for singulating the multiplicity of chips 104 in accordance with various embodiments.

A second trench 122 is illustrated by way of example in this cross-sectional view. The second trench 122 has a maximum trench depth 120d and a first trench width 118d.

In this embodiment, the second trench 122 is formed by means of sawing. The sawing is explained in greater detail below.

In various embodiments, the wafer 102 is sawn from the second wafer surface 126, to put it another way from the rear side of the wafer 102. For this purpose, the wafer 102 is adhesively bonded for example on the first wafer surface 124 and/or the second wafer surface 126 with an adhesive bonding film. The adhesive bonding film prevents a situation in which the two chips 104 can detach from one another during the actual sawing process and are damaged. The wafer 102 is subsequently mounted by means of a mount, for example by means of a vacuum, for sawing.

The wafer 102 is sawn from the second wafer surface 126 by means of a conventional wafer saw having a rotating saw blade. The second trench 122 thus formed reaches from the second wafer surface 126 into the substrate 106 as far as the maximum trench depth 120d. The trench width 118d of the second trench 122 can be predefined on the basis of the thickness of the saw blade used.

During the sawing of the second trench 122, the saw blade does not make direct physical contact with the active region 128 and the dielectric 108. Accordingly, a mechanical loading of the active region 128 and of the dielectric 108 is reduced.

After sawing, the wafer 102 has the form illustrated schematically in FIG. 1C (adhesive bonding film and mount not shown).

In various embodiments, the first trench width 118d can be for example 25 μm to 200 μm, for example 50 μm to 100 μm. In one concrete example, the first trench width 118d of the second trench 122 is approximately 50 μm.

In this example, the maximum trench depth 120d is approximately 185 μm, such that the wafer 102 is locally severed by means of the first trench 112 and the second trench 122. In alternative embodiments, the maximum trench depth 120d may include for example 30% to approximately 99% of the thickness of the substrate 130d, for example 70% to approximately 99% of the thickness of the substrate 130d. The maximum trench depth 120d can be chosen for example depending on the maximum trench depth 114d of the first trench and the thickness of the substrate 130d, such that the wafer 102 is severed on account of the formation of the second trench 122.

The two chips 104 singulated on account of the sawing can be removed from the adhesive bonding film after sawing and are thus singulated, as shown hereinafter in FIG. 1D.

FIG. 1D shows a cross-sectional view of a multiplicity of chips 104 at a fourth point in time of a method for singulating the multiplicity of chips 104 in accordance with various embodiments.

In this embodiment, the first trench 112 extends into the substrate 106 more deeply than the active region 128. In order to open the wafer, a maximum trench depth 120d of the second trench 122 thus suffices on the basis of which the first trench 112 is opened on the rear side, but the active region 128 is not damaged by the two singulation processes. The second trench 122 does not impair the functionality of the two chips 104.

Moreover, it is now possible, on account of the front-side plasma etching for forming the first trenches 112, to arrange the chips 104 laterally closer together, without the electrical components of the chips being damaged by the singulation.

The two separated chips 104 can subsequently be processed further.

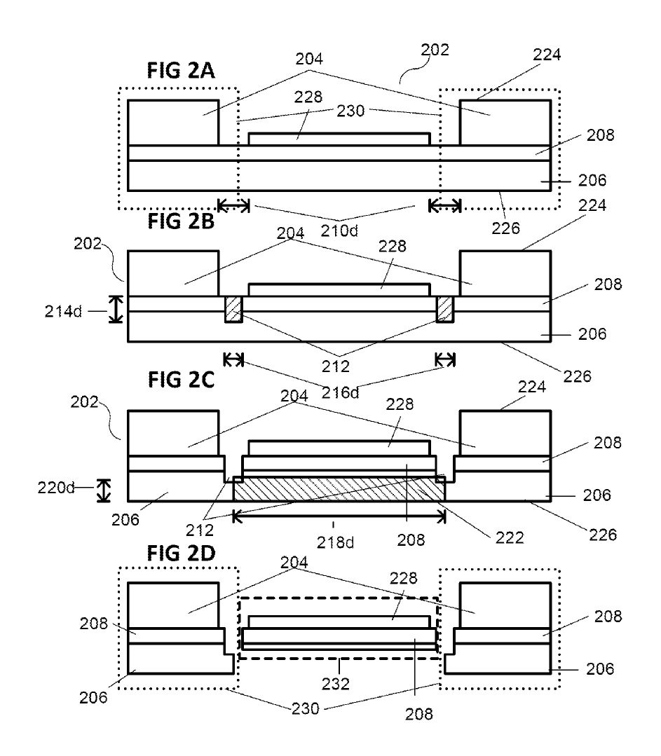

A further embodiment of a method is illustrated schematically in the subsequent figures FIGS. 2A to 2D.

FIG. 2A shows a cross-sectional view of a multiplicity of chips 230 at a first point in time of a method for singulating the multiplicity of chips 230 in accordance with various embodiments.

In this embodiment, a wafer 202 before singulation includes a multiplicity of chips 230, only two chips 230 being illustrated in this cross-sectional view.

The wafer 202 has a first wafer surface 224 and a second wafer surface 226, said second wafer surface being opposite the first wafer surface 224. The wafer 202 includes a substrate 206 and a dielectric 208 above the substrate 206. The wafer 202 includes an active region (not shown) which extends into the substrate 206. Two layer structures 204 are formed above the dielectric 208, wherein each layer structure 204 in each case covers a partial region of the dielectric 208 of a chip 230. The wafer 202 includes a process control element (also referred to as PCM structure) 228. The two chips 230 and the process control element 228 are in each case arranged at a distance 210d from one another, wherein the respective distances can differ from one another.

In this embodiment, the substrate 206 includes doped silicon. Alternatively, the substrate 206 may include other materials, such as, for example, other semiconductor materials or compound semiconductor materials, as explained for the embodiments in accordance with FIG. 1A to FIG. 1D.

In various embodiments, the surface of the substrate 206 can be covered with one or a plurality of layers (not shown), for example produced by means of thermal oxidation and/or by means of a PECVD or ALD method. Such a layer can be for example a dielectric layer, such as, for example, silicon oxide or silicon nitride.

In one example, the dielectric 208 includes a dielectric layer including a “low-k” material, for example porous silicon oxide. In alternative embodiments, the dielectric 208 may include a plurality of different dielectric layers which can be applied for example by means of one or a plurality of CVD and/or ALD methods. The dielectric 208, or various layers which form the dielectric 208, may, as described for example in the context of FIG. 1A, include one or a plurality of metallizations and can be structured, for example by means of photolithography.

In one concrete example, the process control element 228 is formed as an RCM circuit. In alternative embodiments, a process control element can be for example an alignment marking, a structure for monitoring the layer thickness and/or an electrical control structure, for example a PCM structure. In various embodiments, the wafer 202 may include a multiplicity of process control elements 228, wherein the latter can be for example a plurality of mutually different process control elements 228. However, it should be pointed out that the process control elements 228 are optional.

In various embodiments, a layer structure 204, as described for example in the context of FIG. 1A, may include one or a plurality of different layers and structures, for example dielectric layers. In one example, the two layer structures 204 include silicon carbide.

In various embodiments, the distances 210d can be for example in a range of approximately 3 μm to approximately 30 μm, for example in a range of approximately 3 μm to approximately 10 μm. In one concrete embodiment, the plurality of distances 210d are approximately 4 μm.

FIG. 2B shows a cross-sectional view of a multiplicity of chips 230 at a second point in time of a method for singulating the multiplicity of chips 230 in accordance with various embodiments.

This cross-sectional view illustrates by way of example two first trenches 212 between the multiplicity of chips 230.

The two first trenches 212 have a maximum trench depth 214d and a first trench width 216d.

As described in the context of FIG. 1B, the two first trenches 212 can also be formed by means of photolithography and plasma etching. In alternative embodiments, the two first trenches 212 can be formed by means of other etching methods, wherein it is possible to form for example a protective layer having openings as a mask vis-à-vis the etching method on the first wafer surface 224.

In various embodiments, the two first trenches 212 can have a first trench width 216d and a predefined maximum trench depth 214d equal to the above-described ranges of the first trench width 116d and the maximum trench depth 114d, as were described in connection with FIG. 1A to FIG. 1D. The first trench width 216d and the maximum trench depth 214d of different first trenches 212 can be (partly) different among one another. In one concrete example, the first trench width 216d is approximately 3 μm and the maximum trench depth 214d of the two first trenches 212 is approximately 5 μm.

FIG. 2C shows a cross-sectional view of a multiplicity of chips 230 at a third point in time of a method for singulating the multiplicity of chips 230 in accordance with various embodiments.

Subsequently, as described in the context of FIG. 2C, the second trench 222 is formed.

The second trench 222 has a maximum trench depth 220d and a first trench width 218d.

The second trench 222 is formed, as described in the context of FIG. 1C, by means of sawing from the second wafer surface 226. In various embodiments, the course of the second trench 222 corresponds to that or those of the two first trenches 212, such that these are opened on the rear side. Both the two chips 230 and the process control element 228 are singulated as a result.

The second trench 222 runs laterally below the two first trenches 212 and the process control element 228 and does not extend laterally further beyond the two first trenches 212. In other words, even if for example the active region (not shown) of the two chips 230 extends into the substrate 206 more deeply than the two first trenches 212, the electrical components of the active region of the chips 230 (not shown) are not damaged on account of the sawing.

FIG. 2D shows a cross-sectional view of a multiplicity of chips 230 at a fourth point in time of a method for singulating the multiplicity of chips 230 in accordance with various embodiments.

On account of the formation of the second trench 222, an intermediate piece 232 is formed alongside the two chips 230.

In accordance with various embodiments, no process control element 228 is present between the two chips 230 and the intermediate piece 232 principally consists of the substrate 206 and the dielectric 208. In such embodiments, the method can serve for example for protecting the dielectric 208, since the second trench 222 does not make direct physical contact with the dielectric 208 on account of the formation of the two first trenches 212, with the result that the dielectric 208 is subjected to less mechanical loading.

A further embodiment is illustrated in the subsequent figure.

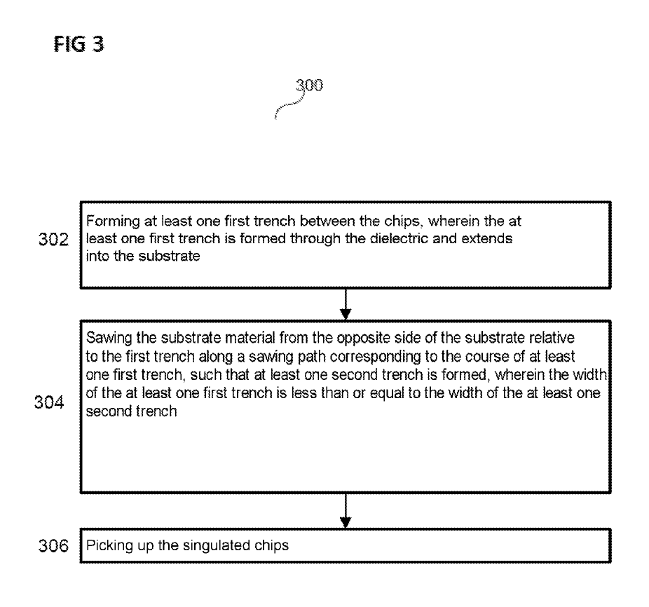

FIG. 3 schematically shows a method 300 for singulating a multiplicity of chips.

In accordance with various embodiments, as described in block 302, at least one first trench is formed by means of plasma etching. The at least one first trench has a maximum trench depth and a first trench width. The at least one first trench is arranged between the multiplicity of chips. The first trench width of the at least one first trench can be less than or equal to the absolute value of a distance of the plurality of distances between the multiplicity of chips.

Afterward, as described in block 304, at least one second trench is formed from the second wafer surface. The at least one second trench has a first trench width and a maximum trench depth. In accordance with various embodiments, the trench width of the at least one second trench can be more than ten times as wide as the trench width of the at least one first trench. The at least one second trench reaches into the substrate and is formed by means of sawing by means of a saw blade. In this regard, the wafer is opened locally by means of the at least one first trench and the at least one second trench, the course of which corresponds to the course of the at least one first trench and the trench width of which is greater than the trench width of the at least one first trench.

Subsequently, as described in block 306, the singulated chips from the multiplicity of chips are picked up and for example then processed further.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

What is claimed is:

1. A method for singulating a multiplicity of chips,
each chip comprising:
a substrate;
an active region arranged at least one of in or on the substrate, at least one electronic component being formed in said active region;
a dielectric above the active region;
the method comprising:
forming at least one first trench between the chips, wherein the at least one first trench is formed through the dielectric and the active regions and extends into the substrate; and
sawing the substrate material from the opposite side of the substrate relative to the first trench along a sawing path corresponding to the course of at least one first trench, such that at least one second trench is formed, wherein the width of the at least one first trench is less than or equal to the width of the at least one second trench.

2. The method of claim 1, further comprising:
before sawing the substrate material, thinning the substrate to a desired substrate thickness.

3. The method of claim 1,
wherein the at least one first trench is formed by etching.

4. The method of claim 3,
wherein the at least one first trench is formed by plasma etching.

5. The method of claim 4,
wherein the composition of the plasma is altered during the plasma etching.

6. The method of claim 4,
wherein the excitation of the plasma is altered during the plasma etching.

7. The method of claim 1,
wherein the sawing is carried out by means of a saw blade.

8. The method of claim 1,
wherein the at least one first trench is formed with a maximum trench depth in a range of approximately 5 μm to approximately 50 μm.

9. The method of claim 1,
wherein the chips are formed at a distance from one another of approximately 3 μm to approximately 10 μm.

10. The method of claim 1,
wherein the dielectric has a dielectric constant of less than or equal to 3.9.

11. The method of claim 1,
wherein the width of at least one second trench is greater than the distance between two adjacent first trenches, such that the two adjacent first trenches are opened on the rear side during the process of sawing the at least one second trench.

12. The method of claim 1,
wherein the at least one first trench extends into the substrate more deeply than the multiplicity of active regions of the multiplicity of chips.
